(19) United States
(12) Patent Application Publication
(10) Pub. No.: US 2023/0105556 A1
(43) Pub. Date: Apr. 6, 2023

(54) SUBSTRATE SUPPORTS INCLUDING BONDING LAYERS WITH STUD ARRAYS FOR SUBSTRATE PROCESSING SYSTEMS

(71) Applicant: LAM RESEARCH CORPORATION, Fremont, CA (US)

(72) Inventors: Siyuan TIAN, Newark, CA (US); Ann ERICKSON, Lake Oswego, OR (US)

(21) Appl. No.: 17/910,139

(22) PCT Filed: Feb. 23, 2021
(86) PCT No.: PCT/US2021/019177

§ 371 Date: Sep. 8, 2022

Related U.S. Application Data
(60) Provisional application No. 62/989,176, filed on Mar. 13, 2020.

(51) Int. Cl. H01L 21/687; H01L 21/67

(52) U.S. Cl. CPC H01L 21/68757; H01L 21/6875; H01L 21/67103; H01L 21/67109; H01L 21/68785

(57) ABSTRACT

A substrate support includes: a baseplate; a top plate disposed above the baseplate and configured to support a substrate during processing of the substrate; and a bonding layer bonding the top plate to the baseplate. The bonding layer includes: multiple studs separating the top plate from the baseplate; and a bonding material disposed in areas laterally surrounding the studs and located between the top plate and the baseplate.

### CROSS-REFERENCE TO RELATED APPLICATIONS

This application claims the benefit of U.S. Provisional Application No. 62/989,176, filed on Mar. 13, 2020. The entire disclosure of the application referenced above is incorporated herein by reference.

### FIELD

The present disclosure relates to bonding layers between ceramic and baseplate layers of substrate supports.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, rapid thermal processing (RTP), ion implant, physical vapor deposition (PVD), and/or other etch, deposition, or cleaning processes. A substrate may be arranged on a substrate support, such as a pedestal, an electrostatic chuck (ESC), etc. in a processing chamber of the substrate processing system. During processing, gas mixtures including one or more precursors may be introduced into the processing chamber and plasma may be used to initiate chemical reactions.

### SUMMARY

A substrate support is provided and includes: a baseplate; a top plate disposed above the baseplate and configured to support a substrate during processing of the substrate; and a bonding layer bonding the top plate to the baseplate. The bonding layer includes: multiple studs separating the top plate from the baseplate; and a bonding material disposed in areas laterally surrounding the studs and located between the top plate and the baseplate.

In other features, the bonding layer includes: a first bonding layer void of studs; and a second bonding layer disposed on the first bonding layer and including the studs. In other features, the first bonding layer is in contact with the baseplate. The second bonding layer is in contact with the top plate.

In other features, the studs are arranged in a symmetric pattern. In other features, the studs are arranged in concentric circles. In other features, a material of the studs is a same material as the bonding material. In other features, the top plate is a ceramic layer in contact with the bonding layer. In other features, the top plate includes one or more heating layers.

In other features, the substrate support further includes a heating layer attached to a bottom surface of the top plate and in contact with the bonding layer. In other features, the baseplate includes coolant channels.

In other features, a method of bonding a top plate to a baseplate of a substrate support is provided. The method includes: determining target stud heights of studs; determining a layout pattern of the studs across the baseplate; based on the target stud heights and the layout pattern, applying a first bonding material on the baseplate to form the studs; curing the studs; placing the top plate on the cured studs; applying at least one of the first bonding material and a second bonding material on the baseplate laterally around the cured studs to form a first bonding layer; and curing the first bonding layer to bond the top plate to the baseplate.

In other features, the method includes forming the first bonding layer with the first bonding material and not the second bonding material. In other features, the method further includes pressing the first bonding layer prior to curing the first bonding layer. In other features, the method further includes grinding the studs to the target stud heights subsequent to curing the plurality of studs.

In other features, the method further includes grinding the top plate, such that a top surface of the top plate is parallel with a bottom surface of the baseplate. In other features, the method further includes determining the target stud heights based on a predetermined thickness of the first bonding layer.

In other features, the method further includes determining one or more of the target stud heights based on at least one of a local surface dimension variation and a thickness offset of the top plate. In other features, the method further includes determining one or more of the target stud heights based on at least one of a local surface dimension variation and a thickness offset of the baseplate.

In other features, the method further includes determining one or more of the target stud heights based on a dimension of a metrology probe dent in a layer of the substrate support. In other features, the method further includes forming a second bonding layer on the baseplate. The first bonding layer is formed on the second bonding layer.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a side cross-sectional view of a substrate support being pressed while forming a bonding layer;

FIG. 2 is a side cross-sectional view of a substrate support illustrating baseplate heights and bonding layer thicknesses;

FIG. 3 is a side cross-sectional view of a portion of a substrate support and a bonding press plate illustrating substrate support top plate and baseplate surface variations;

FIG. 4 is a functional block diagram of an example substrate processing system including a substrate support with a studded bonding layer in accordance with the present disclosure;

FIG. 5 is a cross-sectional side view of a baseplate and example studs of a bonding layer in accordance with the present disclosure;

FIG. 6 is a cross-sectional side view of a portion of a substrate support including example studs prior to applying a final bonding filler material in accordance with the present disclosure;

FIG. 7 is a pair of example plots illustrating a reduction in bond residual range by forming a bonding layer including a stud array in accordance with the present disclosure;

FIG. 8 is a top view of a baseplate having an example stud array in accordance with the present disclosure;

FIG. 9 is a side cross-sectional view of a portion of an example substrate support including a single bonding layer with a stud in accordance with the present disclosure;

FIG. 10 is a side cross-sectional view of a portion of an example substrate support including a stud in one of multiple bonding layers in accordance with the present disclosure;

FIG. 11 is a functional block diagram of a portion of a bonding system including a controller implementing a stud application in accordance with the present disclosure; and

FIG. 12 illustrates a method of forming a substrate support including forming a studded bonding layer in accordance with the present disclosure.

In the drawings, reference numbers may be reused to identify similar and/or identical elements.

### DETAILED DESCRIPTION

Electrostatic chucks (ESCs) can include a top plate formed of ceramic, which is bonded to a liquid cooled baseplate by a bonding layer. The ESCs may include heating elements. The heating elements may be incorporated in the top plates or attached to a bottom surface of the top plates. The bonding layer removes heat generated by plasma and/or the heating elements and transfers the heat to the baseplates of the ESCs. This transfers heat from the wafers supported by the ESCs to the baseplates.

A thermal conductivity level k_{bl} of a bonding layer of an ESC is typically much lower than a thermal conductivity level kₜₚ of a top plate of the ESC. For this reason, there is a significant temperature gradient in the bonding layer during ESC operation. Thicknesses of a bonding layer can be non-uniform and may be a main source of wafer temperature non-uniformity laterally across the wafer from die-to-die. Additional bonding layer non-uniformity exists from ESC-to-ESC and from chamber-to-chamber.

Controlling wafer temperatures with high spatial uniformity is needed for wafer process applications that are sensitive to spatial wafer temperature variations. This is especially true for device structures having small dimensions, such as three-dimensional NAND flash memory structures. High spatial uniformity is also needed for temperature sensitive etch chemistry applications and applications where plasma generated heat needs to be removed from a wafer. Control of ESC bonding layer thickness uniformity is needed for plasma etch processes requiring maintenance of wafer temperatures at predetermined temperatures.

Thermal property performance of a substrate support is directly related to a thickness of a bonding layer of an ESC. Thickness uniformity of a bonding layer of an ESC is affected by both A) a fixture used to form a bonding layer between a top plate and a baseplate, and B) surface variations of the top plate and the baseplate. As an example, a bonding layer may have an average thickness of 100 microns (µm) to 1-2 millimeters (mm) and have a thickness variation of 10-50 µm. Thicknesses of a bonding layer laterally across an ESC are collectively referred to as a bonding layer thickness pattern, which is generally random. For this reason, it is difficult to compensate for these variations. Attempts to compensate for these variations after an ESC is manufactured include complex temperature control systems with long development times.

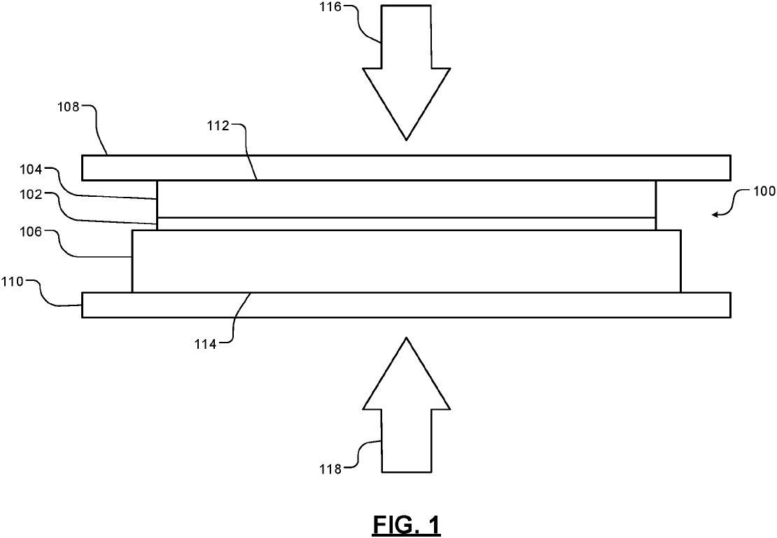

FIG. 1 shows a substrate support 100 with pressure applied while forming a bonding layer 102 between a top plate 104 and a baseplate 106. The substrate support 100 may be an ESC that is pressed between two bonding press plates 108, 110 of a press. The bonding press plates 108, 110 are generally flat. It is difficult to hold the bonding press plate 108 parallel to the bonding press plate 110. The bonding press plates 108, 110 are held in this parallel arrangement in an effort to apply uniform loading forces across a top surface 112 of the top plate 104 and a bottom surface 114 of the baseplate 106. The surfaces 112, 114 are non-bonding surfaces. Force applied to the top plate 104 is represented by arrow 116. Force applied to the baseplate 106 is represented by arrow 118.

It is difficult to control parallelism of the bonding press plates 108, 110, the top plate 104 and the baseplate 106 with micron level precision for a wafer with a diameter larger than, for example, 300 mm. In addition to providing this level of precision, a bonding process needs to be repeatable from ESC to ESC for the entire bonding process.

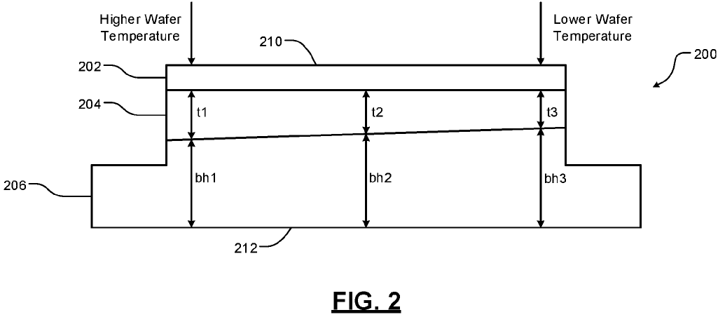

FIG. 2 shows a substrate support 200 including a top plate 202, a bonding layer 204 and a baseplate 206. The baseplate 206 has different heights at various locations (heights h1-h3 are shown) and as a result the bonding layer 204 has different thicknesses (thicknesses t1-t3 are shown) at the corresponding locations. The heights h1-h3 are not equal and, hence, the thicknesses t1-t3 are not equal. The differences between the heights and the thicknesses are exaggerated and shown larger than normal in FIG. 2 for illustration purposes. The differences are actually small and typically not visible to the naked eye. This holds true for other illustrated differences, variations, offsets, etc. shown in FIGS. 2-3 and 5-6 and described herein. During manufacturing, the heights (distances between bottom most surface and top most surface) of a baseplate 206 may vary laterally across the baseplate 206. The heights of a baseplate may refer to local thicknesses of the baseplate. FIG. 2 illustrates an example of this variation. The variation in the heights of the baseplate 206 causes a corresponding variation in thicknesses of the bonding layer 204. This is because a top surface 210 of the top plate 202 is held approximately parallel to a bottom surface 212 of the baseplate 206. In a similar manner, thickness variations of the top plate 202 can also affect thicknesses of the bonding layer 204. As a result of the thickness variations of the bonding layer 204, wafer temperatures are higher over thicker local bonding layer locations as compared to thinner local bonding layer locations.

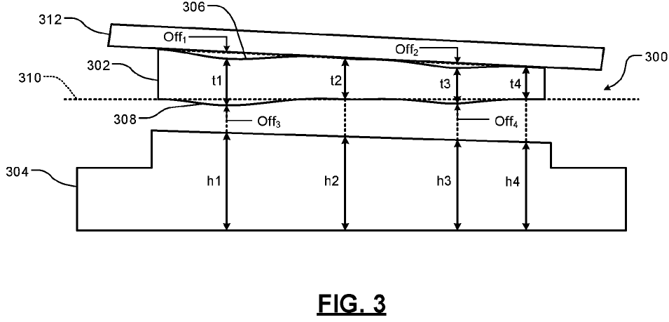

There are multiple challenges in providing a bonding layer with uniform thickness. For example, it is difficult and costly to manufacture and machine a top plate and a baseplate of an ESC with flat parallel top and bottom surfaces and uniform thicknesses and heights. FIG. 3 shows a portion 300 of a substrate support including a top plate 302 and a baseplate 304. The baseplate 304 has height variations (heights h1-h4 are shown) and the top plate 302 has thickness variations (thicknesses t1-t4 are shown). As shown, the thickness can vary and levels of top and bottom surfaces 306, 308 can vary relative to a horizontal reference plane (e.g., horizontal reference plane 310). Example offsets Off₁₋₄ of local top and bottom surfaces of the top plate 302 are shown. The thickness variations can cause a bonding press plate 312 to lie at an angle relative to the horizontal reference plane, which can cause non-uniform loading. In addition, a bonding layer (formed by applying a bonding material to the baseplate followed by pressing the top plate 302, the bonding material, and the baseplate 304) can have non-uniform thickness and a top surface with varying height levels relative to the horizontal reference plane.

It is also difficult to provide a press fixture having bonding plates with flat surfaces. It is also difficult to provide a press fixture that is able to hold the bonding plates in a parallel arrangement and apply uniform forces across the bonding plates in a repeatable manner. The ESC top plate and baseplate, the fixture plates, and the fixture structure need to be machined with micron level precision and inspected. Compared to a wafer diameter, this is an aspect ratio of 300,000:1. As a comparison, a channel hole etched in a three dimensional NAND memory having over 90 layers may have an aspect ratio of 40:1. A bonding process for bonding a top plate to a baseplate needs to include repeatable and accurate metrology and be sufficiently precise and robust such that there is minimal wear on components used in the process.

The examples set forth herein include substrate supports having one or more bonding layers with a stud array. A stud array refers to an arrangement of studs in a predetermined pattern across a baseplate of a substrate support. A stud refers to a column of material (or spacer) that may be pillar-shaped and disposed between layers and/or plates of a substrate support. The columns may or may not have uniform width. The stud arrays provide self-aligned bonding of top plates to baseplates, which reduces radial and azimuthal bond thickness non-uniformity. Improved radial and azimuthal bond thickness uniformity improves ESC radial and azimuthal temperature uniformity. Each stud array is formed as part of a bonding layer to maintain local distances between points on a top plate and corresponding points on a baseplate during a bonding process. This results in a bonding layer with improved thickness uniformity. The formation of the stud array and other remaining portion of the bonding layer improve control over bond spatial thicknesses and ease of manufacturing of substrate supports while reducing corresponding costs.

The stud arrays are formed based on and to compensate for top plate surface variations and baseplate height variations. The stud arrays aid in providing and maintaining distance uniformity between the top plate and the baseplate during bonding. This prevents thickness variations during formation of a remaining portion of the bonding layer. As a result, thickness, height and surface tolerances of top plates and baseplates can be less stringent as compared to ESCs formed using a traditional bonding process that does not include formation of stud arrays. In addition, alignment requirements between a press fixture and plates of an ESC can also be less stringent. The less stringent requirements reduce manufacturing costs of ESCs.

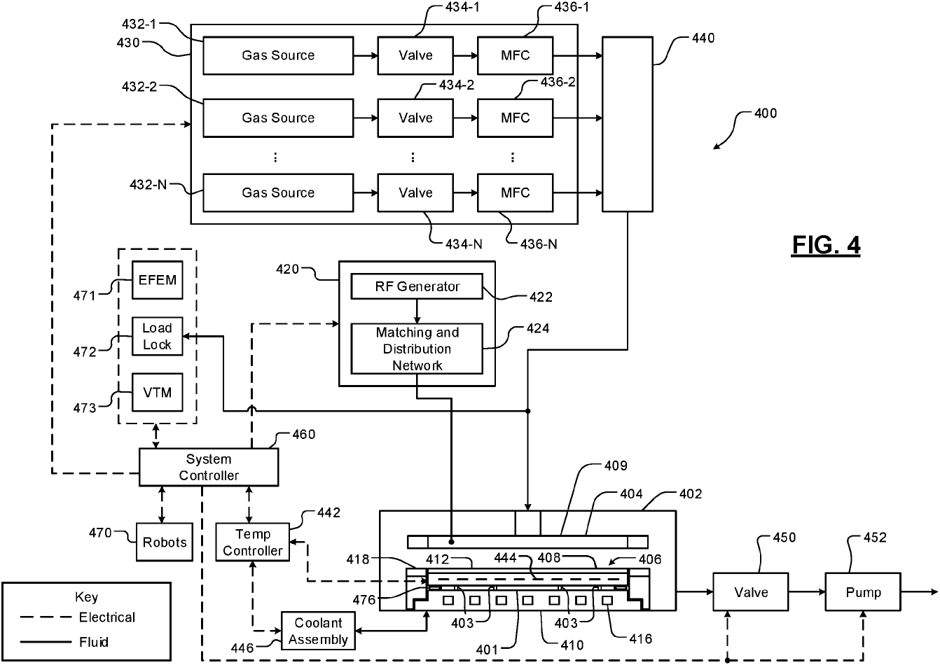

FIG. 4 shows a substrate processing system 400 including a substrate support 406 with a studded bonding layer 401 including studs 403. The substrate support 406 may be formed using the techniques disclosed herein. For example only, the substrate processing system 400 may be used for performing deposition and/or etching using RF plasma and/or other suitable substrate processing. The substrate processing system 400 includes a processing chamber 402 that encloses other components of the substrate processing system 400 and contains the RF plasma. The processing chamber 402 includes an upper electrode 404 and the substrate support 406, which may be an electrostatic chuck (ESC). During operation, a substrate 408 is arranged on the substrate support 406. While a specific substrate processing system 400 and processing chamber 402 are shown as an example, the principles of the present disclosure may be applied to other types of substrate processing systems and chambers, such as a substrate processing system that generates plasma in-situ, that implements remote plasma generation and delivery (e.g., using a plasma tube, a microwave tube), etc.

For example only, the upper electrode 404 may include a gas distribution device such as a showerhead 409 that introduces and distributes process gases. The showerhead 409 may include a stem portion including one end connected to a top surface of the processing chamber 402. A base portion is generally cylindrical and extends radially outwardly from an opposite end of the stem portion at a location that is spaced from the top surface of the processing chamber 402. A substrate-facing surface or faceplate of the base portion of the showerhead 409 includes holes through which process gas or purge gas flows. Alternately, the upper electrode 404 may include a conducting plate and the process gases may be introduced in another manner.

The substrate support 406 includes a conductive baseplate 410 that acts as a lower electrode. The baseplate 410 supports a top plate 412, which may be formed of ceramic. In some examples, the top plate 412 may include one or more heating layers, such as a ceramic multi-zone heating plate. The one or more heating layers may include one or more heating elements, such as conductive traces, as further described below. In another implementation, a heating layer is attached to a bottom surface of the top plate 412.

The bonding layer 401 is disposed between and bonds the top plate 412 to the baseplate 410. The baseplate 410 may include one or more coolant channels 416 for flowing coolant through the baseplate 410. The substrate support 406 may include an edge ring 418 arranged to surround an outer perimeter of the substrate 408.

An RF generating system 420 generates and outputs an RF voltage to one of the upper electrode 404 and the lower electrode (e.g., the baseplate 410 of the substrate support 406). The other one of the upper electrode 404 and the baseplate 410 may be DC grounded, AC grounded or floating. For example only, the RF generating system 420 may include an RF voltage generator 422 that generates the RF voltage that is fed by a matching and distribution network 424 to the upper electrode 404 or the baseplate 410. In other examples, the plasma may be generated inductively or remotely. Although, as shown for example purposes, the RF generating system 420 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

A gas delivery system 430 includes one or more gas sources 432-1, 432-2,..., and 432-N (collectively gas sources 432), where N is an integer greater than zero. The gas sources supply one or more gas mixtures. The gas sources may also supply purge gas. Vaporized precursor may also be used. The gas sources 432 are connected by valves 434-1, 434-2, ..., and 434-N (collectively valves 434) and mass flow controllers 436-1, 436-2, ..., and 436-N (collectively mass flow controllers 436) to a manifold 440. An output of the manifold 440 is fed to the processing chamber 402. For example only, the output of the manifold 440 is fed to the showerhead 409.

A temperature controller 442 may be connected to heating elements, such as thermal control elements (TCEs) 444 arranged in the top plate 412. For example, the heating elements may include, but are not limited to, macro heating elements corresponding to respective zones in a multi-zone heating plate and/or an array of micro heating elements disposed across multiple zones of a multi-zone heating plate. The temperature controller 442 may be used to control the heating elements to control a temperature of the substrate support 406 and the substrate 408.

The temperature controller 442 may communicate with a coolant assembly 446 to control coolant flow through the channels 416. For example, the coolant assembly 446 may include a coolant pump and reservoir. The temperature controller 442 operates the coolant assembly 446 to selectively flow the coolant through the channels 416 to cool the substrate support 406.

A valve 450 and pump 452 may be used to evacuate reactants from the processing chamber 402. A system controller 460 may be used to control components of the substrate processing system 400. One or more robots 470 may be used to deliver substrates onto, and remove substrates from, the substrate support 406. For example, the robots 470 may transfer substrates between an equipment front end module (EFEM) 471 and a load lock 472, between the load lock and a vacuum transfer module (VTM) 473, between the VTM 473 and the substrate support 406, etc. Although shown as separate controllers, the temperature controller 442 may be implemented within the system controller 460. In some examples, a protective seal 476 may be provided around a perimeter of the bonding layer 401 between the top plate 412 and the baseplate 410.

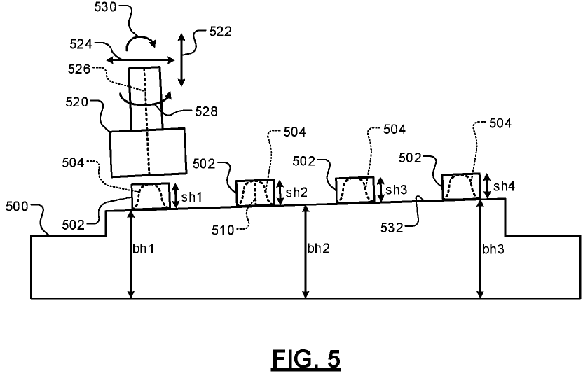

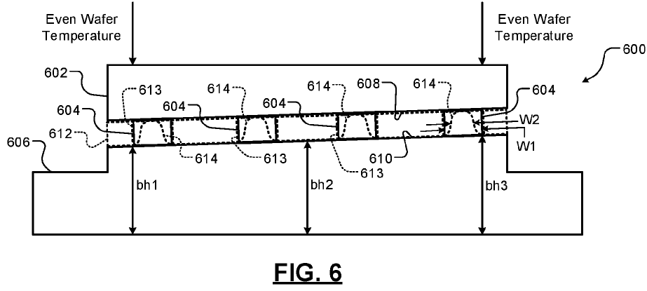

FIG. 5 shows a baseplate 500 and studs 502 of a bonding layer illustrating different example stud formations. As an example, the studs 502 may be rectangular-shaped as shown. In this example, the studs 502 may be formed using a stud holder, an example of which is shown in FIG. 6. The stud holder may be a plate having holes for forming the studs. The holes are filled with a bonding material and cured to form the studs and then the stud holder is removed. In another implementation, multiple cylindrical-shaped rings (or hollow cylinders) are utilized and placed in each stud location and filled with a bonding material to form the studs. The bonding material is cured and the rings are removed. As another example, the studs 502 may be “mound-shaped” as represented by dashed lines 504. In this example, a stud holder is not used and the studs are formed of a highly viscous bonding material. The bonding material may have a same or higher viscosity than the bonding material applied when using a stud holder. The bonding material is applied and cured to provide the mound-shaped studs 504. In these examples, the bonding material when applied is in liquid form.

The studs 502 and/or 504 may be formed to have a same height. This is true although the baseplate 500 may have different heights, as represented by heights bh1-bh3. The heights of the studs 502 and 504 are represented as sh1-sh4 and refer to maximum heights of the bonding material of the studs 502, 504 measured from (i) local top surfaces of the baseplate 500 and/or bottom surface of the studs 502, 504 to (ii) top surfaces of the studs 502, 504. For the studs 504, the stud heights are measured along centerlines of the studs 504 from the local top surfaces of the baseplate 500; an example centerline 510 is shown. In one implementation, the studs 502 and/or 504 are formed to have oversized heights and then grinded to a predetermined height.

An example grinder 520 is shown. The grinder 520 may be moved vertically (represented by arrow 522), moved horizontally (represented by arrow 524), rotated about an axis of rotation 526 (represented by arrow 528), and tilted (represented by arrow 530) such that a bottom surface of the grinder 520 is parallel to a top surface 532 of the baseplate 500. The top surface 532 of the baseplate 500 may be parallel to a top surface of the stud being worked on. In one embodiment, the grinder 520 is moved vertically and in directions parallel to top surfaces of the studs to grind the top surfaces of the studs.

FIG. 6 shows a portion 600 of a substrate support including a top plate 602, studs 604, and a baseplate 606. The studs 604 are shown adjacent to a bottom surface 608 of the top plate 602 and a top surface 610 of the baseplate 606 and have a same height. A stud holder is shown and represented as a dashed box 612 for example purposes only and may be used to form the studs 604 prior to placing the top plate 602 on the studs 604. The stud holder 612 includes holes 613 for formation of the studs. In one embodiment, the stud holder 612 is not used and studs 614 are formed using a highly viscous material.

Spaces surrounding the studs 604 and 614, between the top plate 602 and the baseplate 606, may be filled with a bonding material (also referred to as a final bonding filling material) that is the same, similar or different than the bonding material of the studs 604 and 614. In one embodiment, the bonding material is a same bonding material used to form the studs 604, 614. As an example, after the studs 604, 614 are formed and cured. The studs 604, 614 may then be grinded to a predetermined height. A bonding material may then be applied to the top surface 610 of the baseplate 606 to form a bonding layer. The applied bonding material may slightly cover the studs 604, 614 to provide a thin layer over the studs 604, 614. In one embodiment, the bonding material does not cover the studs 604, 614, but when cured has a same height as the studs 604, 614. The top surface 610 and the top plate 602 may be set on the studs 604, 614 and/or the bonding material. Excess bonding material may be squeezed radially outward past outer edges of the top plate 602 and the baseplate 606. The applied bonding material is cured to form the bonding layer, which includes the studs 604 or 614.

Widths of the studs 604, 614 may not be uniform. In one embodiment, the widths of each of the studs 604 is uniform from the top surface 610 of the baseplate 606 to the bottom surface 608 of the top plate 602. The studs 614 have varying widths. An example width W1 of the studs 604 and an example width W2 of the studs 614 are shown.

Although a thickness of the top plate 602 and a height of the baseplate 606 may vary, since the thickness of the resulting bonding layer has increased uniformity, temperature uniformity across a wafer held by the substrate support is improved. Heights of the studs 604, 614 may be set based on thickness, height and surface variations of the top plate 602 and the baseplate 606.

The studs 604, 614 and corresponding bonding layer and/or other studs and bonding layers disclosed herein may be formed of, for example, a silicone based material including dielectric nanometer-sized particles. The concentration of nanometer sized particles may be adjusted to tune thermal properties of the bonding layers and studs. The examples disclosed herein are also applicable to bonding layers formed of other materials. The baseplate 606 and/or other baseplates disclosed herein may be formed of, for example, an aluminum alloy, an aluminum metal matrix, ceramic and/or other suitable material.

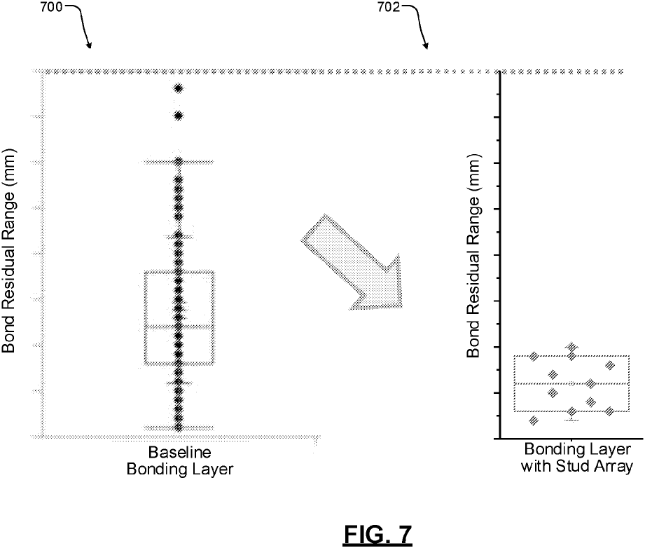

FIG. 7 shows a pair of plots illustrating a reduction in bond residual range by forming a bonding layer including a stud array as disclosed herein. A bond residual range refers to variations in thicknesses of a bonding layer of a substrate support. A first plot 700 shows an example of bond residual range for the baseline bonding layer. The baseline bonding layer does not include studs and is formed using a traditional bonding process. A second plot 702 shows an example of bond residual range for a studded bonding layer (i.e. a bonding layer including studs). For the example shown, the bond residual range for the studded bonding layer is substantially less than the bond residual range for the baseline bonding layer.

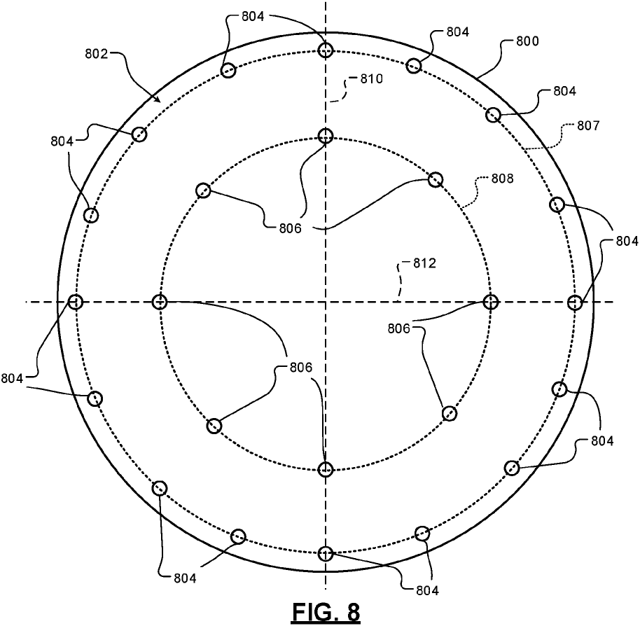

FIG. 8 shows a baseplate 800 having an example stud array 802, which includes an array of studs 804 and 806. In the example shown, the studs 804 are arranged to provide an outermost ring of studs and the studs 806 are arranged to provide another or innermost ring of studs. The rings are concentric circles, represented by dashed circles 807, 808. The studs 804 and 806 are disposed to provide a symmetric pattern of studs relative to one or more radially extending centerlines. A couple of example centerlines 810, 812 are shown. The symmetry may be about two or more centerlines as is the case with the baseplate 800 and stud array 802. Although two rings of studs are shown, any number of rings of studs may be included. The studs may be in various different symmetric and non-symmetric patterns. In one embodiment, the studs are not arranged in rings. In another embodiment, a portion of the studs are arranged in one or more rings and another portion of the studs are not arranged in rings. Although the studs 804, 806 are shown as being circular shaped, the studs may have other shapes.

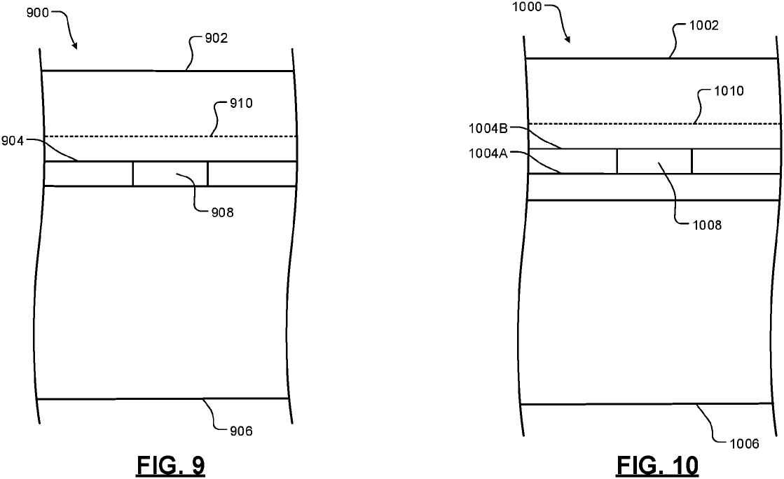

FIG. 9 shows a portion 900 of a substrate support including a top plate 902, a bonding layer 904 and a baseplate 906. The bonding layer 904 includes studs (one stud 908 is shown). The top plate 902 may include one or more layers and/or one or more heating layers. An example heating layer 910 is shown, which may include one or more heating elements, as described above. The heating layer 910 may be a layer applied to a bottom surface of the top plate 902. As an example, the heating layer 910 may be laminated on a bottom surface of the top plate 902 and be disposed between the top plate 902 and the bonding layer 904.

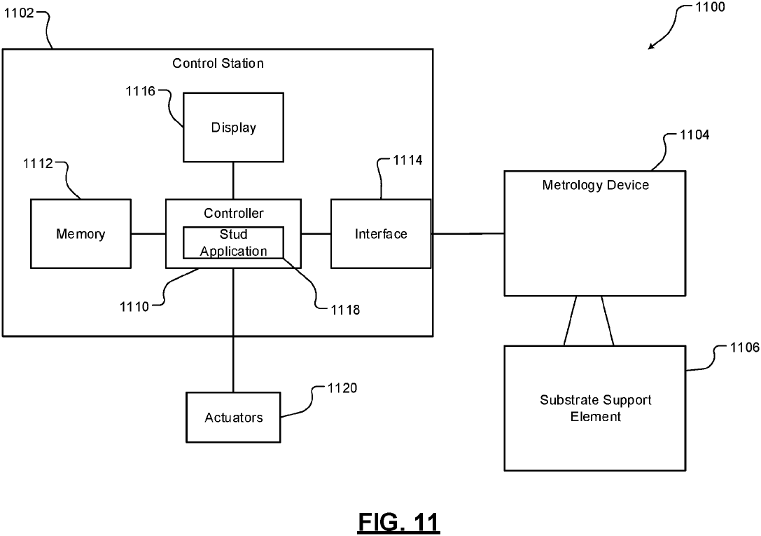

FIG. 10 shows a portion 1000 of a substrate support including a top plate 1002, multiple bonding layers 1004 and a baseplate 1006. The top plate 1002 may include one or more layers and/or one or more heating layers. An example heating layer 1010 is shown, which may include one or more heating elements, as described above. The heating layer 1010 may be attached to a bottom surface of the top plate 1002. The bonding layers 1004 include a bottom bonding layer 1004A and a top bonding layer 1004B. The top bonding layer 1004B includes studs (one stud 1008 is shown). Although two bonding layers are shown, any number of bonding layers may be included. The bottom bonding layer 1004A may be included to, for example, provide a horizontal flat top surface on which to form the top bonding layer 1004B including the studs. This may minimize top surface variations and/or heights, which may exist in the baseplate 1006.

FIG. 11 shows a portion 1100 of a bonding system including a control station 1102, a metrology device 1104 and a substrate support element 1106. The control station 1102 includes a controller 1110, a memory 1112, an interface 1114, and a display 1116. The controller 1110 stores and executes a stud application 1118.

The metrology device 1104 may include, for example, a spectrometer, a scanning electron microscopy (SEM) device, an optical metrology machine, and/or other measuring devices. The metrology device 1104 may be used to measure, for example, dimensions of a top plate, a combination of a top plate and a heating layer, a baseplate, and/or a combination of a baseplate and one or more bonding layers. The metrology device 1104 may include a metrology probe, one or more light sources and/or one or more sensors. The measured values may be provided as inputs via the interface 1114 to the controller 1110, which may store the measured values in the memory 1112.

The controller 1110 may control the metrology device 1104 to measure surfaces, thicknesses, heights, offsets, etc. of substrate support elements, such as a top plate and a base plate (shown as substrate support element 1106). The measurements of the top plate may include measurements associated with having a heating layer attached to the top plate. Similarly, measurements of the baseplate may include measurements associated with one or more non-studded bonding layers. The metrology device may also be used to measure heights of studs. The stud application 1118 may be used to determine target stud heights, as further described below. The stud heights may be determined based on the measurements taken. The controller 1110 may control formation of studs on the baseplate and/or corresponding non-studded layer based on the target stud heights. In an embodiment, the controller 1110 controls operation of the grinder 520 of FIG. 5 via actuators 1120, which may be connected to the grinder 520. The actuators 1120 may include motors to move, rotate and/or tilt the grinder 520. The actuators 1120 may be connected to the grinder 520 via brackets, links, gears and/or other connecting elements.

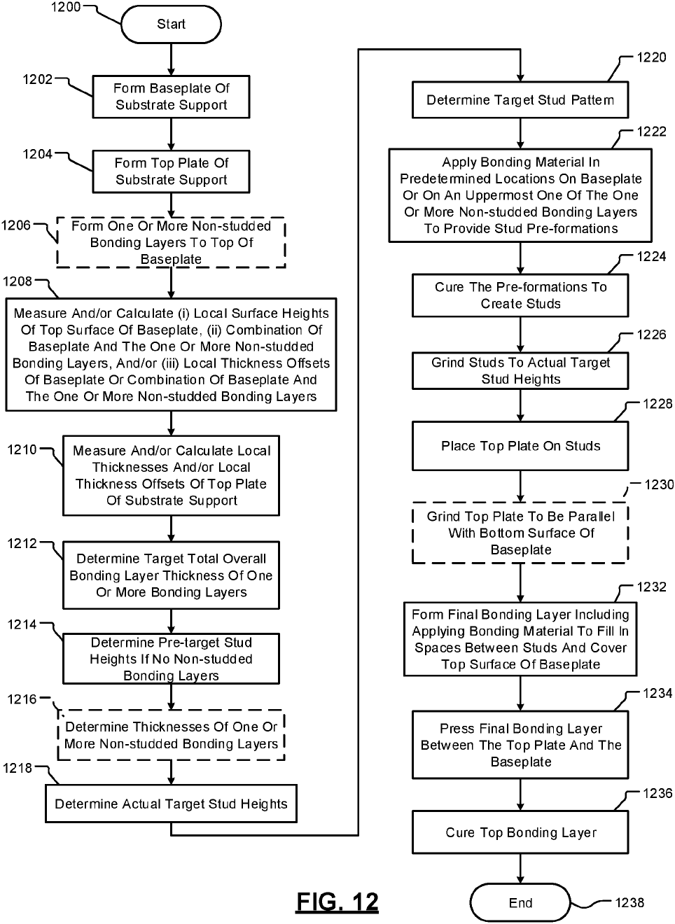

FIG. 12 shows a method of forming a substrate support including forming a studded bonding layer. Although the following operations are primarily described with respect to the implementations of FIGS. 4-11, the operations may be easily modified to apply to other implementations of the present disclosure.

The method may begin at 1200. At 1202, a baseplate of a substrate support is formed. The baseplate may include coolant channels as described above. A top surface of the baseplate may not be parallel to a bottom surface of the baseplate. The top surface may also or alternatively have varying heights, as shown above.

At 1204, a top plate of the substrate support is formed. A top surface of the top plate may not be parallel to a bottom surface of the top plate. In addition or alternatively, thicknesses of the top plate may not be uniform and the top and bottom surfaces of the top plate may have varying heights relative to a horizontal reference plane.

At 1206, one or more non-studded bonding layers may be formed on the top surface of the baseplate. This may include applying a bonding material to the top surface of the baseplate and curing the bonding material in a temperature controlled oven.

At 1208, the controller 1110 performs metrology to measure and/or calculate surface dimensions of the baseplate and local top surface heights of the baseplate. If operation 1206 is performed, the local top surface heights of the uppermost one of the one or more non-studded bonding layers relative to a bottom surface of the baseplate may be determined. Local top surface offsets of the baseplate or thickness offsets may also be determined. Examples of surface and thickness offsets for a top plate are shown in FIG. 3. The local top surface offsets and thickness offsets of the baseplate refer to similar aspects of the baseplate as the surface and thickness offsets of the top plate.

At 1210, the controller 1110 performs metrology to measure and/or calculate surface dimensions and local thicknesses of the top plate. The local thicknesses may include a combination of the top plate and a heating layer. For example, if the heating layer is attached to a bottom surface of the top plate, then a thickness may refer to a distance between a top surface of the top plate and a bottom surface of the heating layer. Local surface and thickness offsets may also be determined, examples of which are shown in FIG. 3.

At 1212, the controller 1110 determines a target overall bonding layer thickness of one or more bonding layers. In a local area, this thickness includes a sum of the thicknesses of the one or more bonding layers. This may be based on, for example, target predetermined wafer temperatures, top plate temperatures, and/or other parameters.

At 1214, the controller 1110 via the stud application 1118 determines pre-target stud heights as if no non-studded bonding layers are included. This may be based on the target overall bonding layer thickness, the local surface and/or thickness offsets of the top plate, the local surface and/or thickness offsets of the baseplate, the surface dimensions of a bottom surface of the top plate, and the surface dimensions of the top surface of the baseplate. As an example, each of the pre-target stud heights may be equal to the target overall bonding layer thickness minus a local thickness offset of the top plate plus a local thickness offset of the baseplate.

At 1216, the controller 1110 via the stud application 1118 may determine thicknesses of one or more non-studded bonding layers if applied to the baseplate, such as at 1206.

At 1218, the controller 1110 via the stud application 1118 may determine actual (or final) target stud heights. This may be for a machining process of the studs. As an example, each of the actual target stud heights may be equal to the corresponding one of the pre-target stud heights minus a corresponding local thickness of the one or more non-studded bonding layers under the corresponding stud plus a probe compensation value. If a probe is used to measure a height of a non-studded bonding layer, the probe may cause a dent in the non-studded bonding layer when contacting the non-studded bonding layer. This accounts for the depth of the dent. If a non-studded bonding layer is not included and the probe is used to measure a height of the baseplate, then a dent does not occur and the compensation value is zero.

At 1220, the controller 1110 via the stud application 1118 determines a target stud pattern of studs to be formed on the baseplate and/or the one or more non-studded bonding layers. This may include determining the number of studs, the sizes and shapes of the studs, and the locations of the studs.

At 1222, bonding material is applied in the predetermined locations on the baseplate or on the uppermost one of the one or more non-studded bonding layers to begin formation of the studs and provide stud pre-formations. At 1224, the stud pre-formations are cured in a temperature controlled oven to solidify the stud pre-formations to provide resulting studs.

At 1226, the studs may be grinded to the actual target stud heights. This occurs if, for example, the stud pre-formations are oversized to be taller than the actual target stud heights. This grinding may also account for addition of the top and/or final bonding layer formed at 1232, by reducing heights of the studs to be shorter than the actual target stud heights by the estimated thickness of the added bond material on the studs. For example, when the top and/or final bonding layer is formed a small amount of bonding material may be applied on tops of the studs. This grinding may account for the additional material such that the resulting heights of the studs after the material is added match the actual target stud heights. The grinding may include planning top surfaces of the studs.

At 1228, the top plate is placed on the studs and aligned with the baseplate. At 1230, if the top surface of the top plate is not parallel with a bottom surface of the baseplate, the top surface of the top plate may be machined. This assures that the top surface of the top plate is parallel with the bottom surface of the baseplate for uniformly distributed loading when applying pressure via opposing bonding press plates. Uniformly distributed loading aids in providing a resulting overall bonding layer (including one or more bonding layers) with uniform or close to uniform thickness. In one embodiment, when the formation of the studs results in a bonding layer with sufficient thickness uniformity, operation 1230 is not performed. By providing a resultant one or more bonding layers with improved overall thickness uniformity, temperature distribution uniformity is improved.

At 1232, a final bonding layer is formed. A much larger volume of bonding material is used to form the final bonding layer than used to form the studs. This includes applying or injecting a bonding material to a top surface of the baseplate or a top surface of the uppermost one of the one or more non-studded bonding layers if included. The bonding material fills areas between and around the studs and covers the top surface of the baseplate or top surface of the uppermost one of the one or more non-studded bonding layers.

At 1234, the final bonding layer is pressed between the top plate and the baseplate to remove excess bonding material and fill in gaps. A uniformly distributed amount of force is applied across the studs. The studs are elastic such that after being compressed the studs return to an original cured form (or original height) that existed prior to compression. A small amount of deformation of the studs occurs when compressed. At 1236, the substrate support is removed from the press fixture and the final bonding layer is cured. This may include baking the substrate support in a temperature controlled oven. The method may end at 1238.

The above-described operations are meant to be illustrative examples. The operations may be performed sequentially, synchronously, simultaneously, continuously, during overlapping time periods or in a different order depending upon the application. Also, any of the operations may not be performed or skipped depending on the implementation and/or sequence of events.

The above-describe method includes determining stud array heights to compensate for variations in incoming (or newly provided) top plate and baseplate material, structural surfaces, and/or layer dimension. The method includes a disclosed bonding process that may include preparing a baseplate structural surface prior to bonding to a top plate. This may include (i) forming a studs followed by forming a remainder of a bonding layer, or (ii) forming one or more non-studded bonding layers followed by forming a studded bonding layer. The method provides a substrate support that is able to satisfy increased surface temperature uniformity requirements. Wafer temperature azimuthal and radial uniformity is improved. Wafer temperature azimuthal uniformity is influenced by bond thickness variation, which can be significantly reduced by about 50% using the disclosed method as compared to bond thickness variation experienced using a traditional bonding process. This means for substrate support operating conditions on wafer temperature uniformity is improved by about 50%.

Cost of substrate supports formed using the disclosed method is also reduced because the bonding process is less sensitive to variations in incoming top plates and baseplates and variations associated with bonding and metrology. Traditionally, a highly stringent screening of incoming top plate and baseplates was needed to assure accurate dimensions with tight tolerances and repeatable metrology. With the disclosed method, the tolerances can be less stringent, which reduces manufacturing time and costs. The amount of machining performed during the disclosed method to, for example, machine the stud arrays is low due to the simple structures of the studs and corresponding layers being machined. The amount of machining is also low due to the use of the same bonding materials and bonding layer formation process for studs and other portions of the bonding layers.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from multiple fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate support comprising:
a baseplate;
a top plate disposed above the baseplate and configured to support a substrate during processing of the substrate; and
a bonding layer bonding the top plate to the baseplate, wherein the bonding layer comprises
a plurality of studs separating the top plate from the baseplate and contacting the baseplate, and
a bonding material disposed in areas laterally surrounding the plurality of studs and located between the top plate and the baseplate.

2. The substrate support of claim 23, wherein the bonding layer comprises:
a first bonding layer void of studs, and
a second bonding layer disposed on the first bonding layer and comprising the plurality of studs.

3. The substrate support of claim 2, wherein:
the first bonding layer is in contact with the baseplate; and
the second bonding layer is in contact with the top plate.

4. The substrate support of claim 1, wherein the plurality of studs are arranged in a symmetric pattern.

5. The substrate support of claim 1, wherein the plurality of studs are arranged in concentric circles.

6. The substrate support of claim 1, wherein a material of the studs is a same material as the bonding material.

7. The substrate support of claim 1, wherein the top plate is a ceramic layer in contact with the bonding layer.

8. The substrate support of claim 1, wherein the top plate comprises one or more heating layers.

9. The substrate support of claim 1, further comprising a heating layer attached to a bottom surface of the top plate and in contact with the bonding layer.

10. The substrate support of claim 1, wherein the baseplate comprises coolant channels.

11. A method of bonding a top plate to a baseplate of a substrate support, the method comprising:
determining target stud heights of a plurality of studs;
determining a layout pattern of the plurality of studs across the baseplate;
based on the target stud heights and the layout pattern, applying a first bonding material on the baseplate to form the plurality of studs;
curing the plurality of studs;
placing the top plate on the plurality of cured studs;
applying at least one of the first bonding material and a second bonding material on the baseplate laterally around the plurality of cured studs to form a first bonding layer; and
curing the first bonding layer to bond the top plate to the baseplate.

12. The method of claim 11, comprising forming the first bonding layer with the first bonding material and not the second bonding material.

13. (canceled)

14. The method of claim 11, further comprising grinding the plurality of studs to the target stud heights subsequent to curing the plurality of studs.

15. The method of claim 11, further comprising grinding the top plate, such that a top surface of the top plate is parallel with a bottom surface of the baseplate.

16. The method of claim 11, further comprising determining the target stud heights based on a predetermined thickness of the first bonding layer.

17. The method of claim 11, further comprising determining one or more of the target stud heights based on at least one of a local surface dimension variation and a thickness offset of the top plate.

18. The method of claim 11, further comprising determining one or more of the target stud heights based on at least one of a local surface dimension variation and a thickness offset of the baseplate.

19. The method of claim 11, further comprising determining one or more of the target stud heights based on a dimension of a metrology probe dent in a layer of the substrate support.

20. The method of claim 11, further comprising forming a second bonding layer on the baseplate,
wherein the first bonding layer is formed on the second bonding layer.

21. The substrate support of claim 1, wherein heights of the plurality of studs are at least one of (i) based respectively on corresponding local thickness offsets of the baseplate, and (ii) based respectively on corresponding local thickness offsets of the top plate.

22. The substrate support of claim 21, wherein:
the heights of the plurality of studs are based respectively on corresponding local thickness offsets of the baseplate; and
the local thickness offsets of the baseplate refer to variations in distances between a reference plane and top or bottom surfaces of the baseplate.

23. The substrate support of claim 21, wherein:
the heights of the plurality of studs are based respectively on corresponding local thickness offsets of the baseplate; and
the local thickness offsets of the top plate refer to variations in distances between a reference plane and top or bottom surfaces of the top plate.

24. A substrate support comprising:
a baseplate;
a top plate disposed above the baseplate and configured to support a substrate during processing of the substrate; and
a bonding layer bonding the top plate to the baseplate, wherein the bonding layer comprises
a plurality of studs separating the top plate from the baseplate, and
a bonding material disposed in areas laterally surrounding the plurality of studs and located between the top plate and the baseplate,
wherein heights of the plurality of studs are at least one of (i) based respectively on corresponding local thickness offsets of the baseplate, and (ii) based respectively on corresponding local thickness offsets of the top plate.

25. The substrate support of claim 24, wherein:
the heights of the plurality of studs are based respectively on corresponding local thickness offsets of the baseplate; and
the local thickness offsets of the baseplate refer to variations in distances between a reference plane and top or bottom surfaces of the baseplate.

26. The substrate support of claim 24, wherein:
the heights of the plurality of studs are based respectively on corresponding local thickness offsets of the baseplate; and
the local thickness offsets of the top plate refer to variations in distances between a reference plane and top or bottom surfaces of the top plate.
